(19) United States
(12) Patent Application Publication
(10) Pub. No.: US 2010/0216067 A1
(43) Pub. Date: Aug. 26, 2010

(54) LITHOGRAPHIC PRINTING PLATE DEVELOPING COMPOSITIONS

(76) Inventors: Gary R. Miller, Fort Collins, CO (US); Melanie A. Roth, Loveland, CO (US); Heidi M. Munnelly, Windsor, CO (US); Anthony P. Kitson, Greeley, CO (US); Scott A. Beckley, Windsor, CO (US); John Kalamen, Loveland, CO (US); Oliver Piestert, Schwetzingen (DE)

Correspondence Address: Amelia Buharin;Patent Legal Staff, Eastman Kodak Company, 343 State Street, Rochester, NY, 14650-2201, US

(21) Appl. No.: 12/389,461

(22) Filed: Feb. 20, 2009

(51) Int. Cl. G03G 9/12; G03F 7/20

(52) U.S. Cl. 430/108.4; 430/108.1; 430/302

(57) ABSTRACT

A concentrated developer can be prepared with less than 60 weight % water and still remain in a single phase with little or no haze or precipitation. This developer concentrate also includes a water-soluble or water-miscible organic solvent, one or more alkyl ether carboxylic acid, coconut oil alkanolamine, coconut fatty alcohol polyglycol ether, β-naphtholethoxylate, and block propylene oxide-ethylene oxide in an amount of at least 0.1 and up to 50 weight % solids, and optionally an alkyl naphthalene sulfonate in an amount of up to 40 weight % solids. The developer concentrate can be diluted up to 80:1 or greater with water and used to process imaged lithographic printing plate precursors.

### FIELD OF THE INVENTION

This invention relates to lithography and to alkaline processing solutions that can be used to process imaged elements such as lithographic printing plate precursors. These processing solutions are free of silicates and can be formulated in highly concentrated form and used in diluted form. This invention also relates to methods of processing such elements that can be either positive- or negative-working.

### BACKGROUND OF THE INVENTION

Recent developments in the field of printing plate precursors concern the use of imageable layer compositions that can be imaged by means of lasers or laser diodes. Laser exposure does not require conventional silver halide graphic arts films as intermediate information carriers (or “masks”) since the lasers can be controlled directly by computers. High-performance lasers or laser-diodes that are used in commercially-available image-setters generally emit radiation having a wavelength of at least 700 nm, and thus the imageable layer compositions are sensitive in the near-infrared or infrared region of the electromagnetic spectrum. However, other useful radiation-sensitive compositions are designed for imaging with ultraviolet or visible radiation.

There are two possible ways of using imageable layer compositions for the preparation of printing plates. For negative-working printing plates, exposed regions in the imageable layer are hardened and non-exposed regions are washed off during development. For positive-working printing plates, the exposed regions are dissolved in a developer and the non-exposed regions become an image.

Various aqueous alkaline compositions (developers) are known for processing imaged negative-working and positive-working elements to provide lithographic printing plates. For example, high pH developers containing 5-30% alkali and 0.1-10% of an ethylene oxide/propylene oxide block copolymer are described in U.S. Pat. No. 4,945,030 (Turner et al.), and other developers containing a thickener such as glycerin and a SiO₂ to M₂O weight ratio of at least 0.3 are described in U.S. Pat. No. 5,851,735 (Miller et al.).

High pH developers may also include various surfactants, anti-foaming agents, silicates, alkali hydroxides, suspension agents including alkyleneoxide compounds and sugars as described for example in U.S. Pat. No. 5,670,294 (Piro) and U.S. Pat. No. 7,147,995 (Takamiya).

Lithographic printing plate developers generally contain at least 75% water so they are “ready-to-use” and can be pumped directly into a developer reservoir in a processor apparatus. This is advantageous as the user does not need to dilute or mix the solutions before they are used and the developer composition is consistent from batch to batch. The manufacturer can control the quality of the developer so the user has no opportunity to improperly mix or dilute the solution.

However, there are significant disadvantages with ready-do-use developers, primarily the high costs of shipping large volumes of water throughout the world to users. Moreover, most ready-to-use developers are not suitable for processing a variety of printing plate precursors. Some precursors require high pH (“active”) developers while others need lower pH (“mild”) developers.

Formulating and using “concentrated” developers, while they provide a number of advantages, can be difficult. Users may contaminate the developer during dilution and without sophisticated manufacturing measuring equipment and stirrers, the end-use concentration may vary as being either too weak or two strong (“active”). A properly formulated concentrated developer, then, must form a stable solution with little or no phase separation or precipitation that can alter or vary the developer activity. Moreover, the developers must also be free of phase separation and precipitates, and surfactants used to provide these results must not interfere with processing.

The formulation of what are known as “extreme” concentrates is even more difficult because the concentration of water is minimized and their stability can be a significant concern.

### SUMMARY OF THE INVENTION

This invention provides a developer concentrate that is free of silicates, and comprises:

a. no more than 60 weight % water,

b. a water-soluble or water-miscible organic solvent,

c. one or more alkyl ether carboxylic acid, coconut oil alkanolamine, coconut fatty alcohol polyglycol ether, 0-naphtholethoxylate, and block propylene oxide-ethylene oxide in an amount of at least 1 weight % and up to 50 weight % solids, and
d. optionally, an alkyl naphthalene sulfonate in an amount of up to 40 weight % solids.

A developer solution can be provided by diluting the developer concentrate of this invention with at least 2 parts water to 1 part developer concentrate.

This invention also provides a method of providing a lithographic printing plate comprising:
A) imagewise exposing a lithographic printing plate precursor to provide both exposed and non-exposed regions, and
B) processing the imagewise exposed printing plate precursor with a developer solution provided by diluting the developer concentrate of this invention with at least 2 parts water to 1 part developer concentrate.

We have found a developer formulation for lithographic printing plate processing that can be prepared in the form of an “extreme” concentrate without evidence of phase separation and precipitation. Our invention can be diluted to various strengths and used to process a variety of imaged elements including both imaged negative- and positive-working printing plate precursors. In addition, the developer concentrate can be used to make either a replenisher or regenerator for the seasoned developer. We found that both the developer concentrate and diluted developer solutions are stable, clear solutions and do not readily form precipitates or separate into multiple phases. Thus, our invention solves the problems with known concentrates and diluted working strength developers.

We unexpectedly found that these advantages can be achieved by using certain classes of surfactants that stabilize the concentrated and diluted developers without interfering with the processing activity. In most instances, a mixtures of two different classes of surfactants are used for best results.

### DETAILED DESCRIPTION OF THE INVENTION

### DEFINITIONS

Unless the context indicates otherwise, when used herein, the terms “developer concentrate” and “developer solution” are meant to be references to embodiments of the present invention. The diluted working strength solution can also be known as a “developer”.

In addition, unless the context indicates otherwise, the various surfactant classes described herein, “amine base”, “water-soluble or water-miscible organic solvent”, and similar terms also refer to mixtures of such components. Thus, the use of the articles “a”, “an”, and “the” is not necessarily meant to refer to only a single component.

The term “single-layer imageable element” refers to an imageable element having only one imageable layer that is essential to imaging, but as pointed out in more detail below, such elements may also include one or more layers under or over (such as a overcoat or topcoat) the imageable layer to provide various properties. The single-layer imageable elements can be either positive- or negative-working elements.

The term “multilayer imageable element” refers to an imageable element having at least two imageable layers that are essential to imaging, but such elements can also include other optional layers for various purposes other than imaging. Such elements are generally positive-working in nature.

Unless otherwise indicated, percentages refer to percents by dry weight.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

The term “polymer” refers to high and low molecular weight polymers including oligomers and includes homopolymers and copolymers.

The term “copolymer” refers to polymers that are derived from two or more different monomers.

The term “backbone” refers to the chain of atoms in a polymer to which a plurality of pendant groups are attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

By “silicate” we mean SiO₂ and by “alkali silicate” or “metal silicate”, we mean M₂SiO₃ wherein M is an alkali metal such as sodium or potassium.

When used in reference to the developer composition, “conductivity” is measured in milliSiemens/cm (mS/cm) using a conventional conductivity meter.

The term “replenisher” refers to a composition that has essentially the same composition and pH as the developer solution being using during processing, that is added as needed to replace water volume and components that are lost during processing. In many instances, the developer solution is used as its own replenisher. While the replenisher can increase activity in a “seasoned” or depleted developer solution, it does not increase the activity greater than the “fresh” unused developer solution.

The term “regenerator” refers to a composition that has greater activity than a “fresh” unused developer solution and it used to maintain both volume and activity of the original developer solution.

### Developer Concentrate and Solution

The developer concentrate is in liquid form and can be used to prepare a developer solution that can be used in a processing method for developing imaged positive-working or negative-working lithographic printing plate precursors (or imageable elements) that are described in more detail below.

The developer concentrate is free of silicates and alkali hydroxides, and comprises no more than 60 weight % water, or no more than 50 weight % water, or in some embodiments, no more than 40 weight % water. Some other embodiments have no more than 30 weight % water.

The developer concentrate also includes up to 50 weight % and typically from about 25 to about 45 weight % of a water-soluble or water-miscible organic solvent, including but not limited to, alcohols such as benzyl alcohol or 2-phenoxyethanol, diacetone alcohol, tetrahydrofurfuryl alcohol, and di(propylene glycol)methyl ether, and mixtures thereof.

Surfactants in the developer concentrate are chosen from one or more of the following classes of anionic and nonionic surfactants: alkyl ether carboxylic acids (such as Alkpo LF2 from KAO, Japan), coconut oil alkanolamines (such as Calsuds® CD-6 from Pilot), coconut fatty alcohol polyglycol ethers (such as Genapol C200 from Clariant), β-naphtholethoxylate (such as Lugalvan® BNO 12 and 24 from BASF), and block propylene oxide-ethylene oxides (such as Pluronic® L64 from BASF), in an amount of at least 1 weight % solids and typically from about 1 to about 50 weight % solids.

The developer concentrate optionally includes one or more alkyl naphthalene sulfonates (such as Petro AA from Akzo Nobel) in an amount of up to 40 weight % solids or typically from about 15 to about 30 weight % solids.

Thus, in some embodiments, the developer concentrate includes:

one or more alkyl ether carboxylic acid, coconut oil alkanolamine, coconut fatty alcohol polyglycol ether, β-naphtholethoxylate, and block propylene oxide-ethylene oxide that are present in an amount of from about 0.1 to about 20 weight %, and

an alkyl naphthalene sulfonate that is present in an amount of from about 15 to about 30 weight %.

In such embodiments, the ratio of the first type of surfactant to the alkyl naphthalene sulfonate can be from about 0.1:1 to about 1:100.

In still other embodiments, the developer concentrate further comprises an amine base including but not limited to, monoethanolamine, diethanolamine, and triethanolamine in an amount of from about 0.1 to about 20 weight %.

The pH of the developer concentrate is generally from about 7 to about 13 or typically from about 9 to about 12.5. This pH may change by up to 3 pH units upon dilution depending upon the desired dilution to form developer solutions.

The developer concentrate can be readily formulated by mixing the various components, in any order, with the desired amount of water are appropriate stirring or agitation to form the single-phase stable liquid concentrate. It can be packaged and stored in various size containers.

As noted above, the developer concentrate can be diluted appropriately for processing various imaged lithographic printing plate precursors. For example, a developer solution can be provided by diluting the developer concentrate with at least 2 parts water to 1 part developer concentrate, or typically with at least 3 parts of water to 1 part developer concentrate and up to 10 parts of water per 1 part of developer concentrate.

The resulting developer solution can have a pH of from about 7 to about 12.

This dilution can be carried out prior to use of the developer solution for processing (step B), or it can be carried out simultaneously with the processing step, using suitable metering apparatus and plumbing.

### Imageable Elements

The developer concentrates can be used to provide developer solutions that can be used for the production of printing plates suitable or intended primarily for lithographic printing, letterpress printing, gravure printing, and screen printing, or for preparing photoresist images. For example, the invention can be used to process imaged lithographic printing plate precursors of various types. For example, such precursors can be “analog” photosensitive imageable elements that are sensitive to actinic radiation (UV or visible radiation) and that are usually imaged using graphic arts films as mask elements. Such precursors generally include a light-hardenable imageable layer (for example, containing a photosensitive diazo compound, naphthoquinonediazides, diazo resins, or photosensitive polymers) disposed on a substrate (such as an aluminum substrate). Representative examples of such photosensitive lithographic printing plate precursors are described, for example, in EP 080 042 (Kita et al.), and U.S. Pat. No. 4,997,745 (Kawamura et al.), U.S. Pat. No. 5,155,012 (Joerg et al.), U.S. Pat. No. 5,340,699 (Haley et al.), U.S. Pat. No. 5,545,676 (Palazzotto et al.), U.S. Pat. No. 5,599,650 (Bi et al.), and U.S. Pat. No. 6,365,330 (Leichsenring et al.).

While the invention can be used to develop or process any imaged imageable element, generally it is used to process thermally imaged (such as computer-to-plate) negative-working and positive-working lithographic printing plate precursors.

Some embodiments of such positive-working imageable elements comprise an alkaline solution removable inner layer and an ink-receptive outer layer. In other embodiments, the imageable elements include only a single imageable layer that is removable in an alkaline solution. The imageable layer(s), which are composed of water- or alkali-soluble polymeric compositions, are generally disposed on an aluminum-containing substrate. More details of such elements are provided as follows.

The substrates are generally provided initially as an electrochemically grained support having aluminum as the predominant component, and including supports of pure aluminum and aluminum alloys. Thus, the electrochemically grained metal support can be composed of pure aluminum, aluminum alloys having small amounts (up to 10% by weight) of other elements such as manganese, silicon, iron, titanium, copper, magnesium, chromium, zinc, bismuth, nickel, or zirconium, or be polymeric films or papers on which a pure aluminum or aluminum alloy sheet is laminated or deposited (for example, a laminate of an aluminum sheet and a polyester film).

The thickness of the resulting aluminum-containing substrate can be varied but should be sufficient to sustain the wear from printing and thin enough to wrap around a printing form. Generally, support sheets have a thickness of from about 100 to about 700 μm.

The substrates can be prepared as continuous webs or coiled strips to provide substrates as continuous webs that can be cut into desired sheets at a later time.

The aluminum surface of the support is generally cleaned, roughened, and anodized using suitable known procedures. For example, the surface may be roughened (or grained) by known techniques, such as mechanical roughening, electrochemical roughening, or a combination thereof (multi-graining). Electrochemically graining can be carried out in a suitable manner as described for example in U.S. Pat. No. 7,049,048 (Hunter et al.). In some embodiments, the surface of the aluminum-containing support can be electrochemically grained using the procedure and chemistry described in U.S. Patent Application Publication 2008/0003411 (Hunter et al.).

While this electrochemically grained metal sheet can now be used as a substrate, it is usually subjected to additional treatments before such use. Generally, the electrochemically grained metal surface is etched with an alkaline solution to remove at least 100 mg/m², and typically to remove from about 100 to about 1000 mg/m². The electrochemically grained aluminum support can then be anodized in an alternating current passing through a sulfuric acid solution (5-30%) to form an oxide layer on the metal surface. When phosphoric acid is used for anodization, the conditions may be varied, as one skilled in the art would readily know.

The aluminum-containing support is then usually treated to provide a hydrophilic interlayer to render its surface more hydrophilic with, for example, a post-treatment solution containing a homopolymer of vinyl phosphonic acid (PVPA) or a vinyl phosphonic acid copolymer such as a copolymer derived from vinyl phosphonic acid and (meth)acrylic acid (that is either methacrylic acid, acrylic acid, or both). Other treatments are described in U.S. Pat. No. 7,416,831 (Hayashi et al.). Typically, the electrochemically grained, etched, and anodized aluminum support is treated with poly(vinyl phosphonic acid).

The backside (non-imaging side) of an aluminum substrate may be coated with antistatic agents and/or slipping layers or a matte layer to improve handling and “feel” of the imageable element.

The substrates can be used to prepare a wide variety of imageable elements including negative- and positive-working imageable elements that can be imaged and processed for use as lithographic printing plates. Such imageable elements are generally lithographic printing plate precursors and include one or more ink-receptive layers disposed on the substrate. That is, they include one or more imageable layers besides any layers generally used as subbing layers, adhesion layers, protective cover layers, or for other non-imaging purposes.

The imageable layers (hence elements) can be made sensitive to any suitable thermal imaging radiation including UV, visible, and infrared radiation having a maximum exposure wavelength of from about 150 to about 1500 nm. The imageable elements can be designed for imaging on a variety of processing apparatus and for development off-press using the present invention in conventional developing apparatus.

There are numerous publications in the art relating to negative-working imageable compositions and elements that can be processed with the developer composition. Useful negative-working compositions generally include a polymerizable component (such as a free-radically polymerizable monomer, oligomer, or polymer, or acid-crosslinked compound), an initiator composition (such as compounds that generate free radicals, or promote cationically or acid-catalyzed polymerization or crosslinking), appropriate sensitizers or radiation absorbing compounds for a specific radiation sensitivity (also known as photothermal conversion materials) such as carbon blacks, IR dyes, coumarins, onium salts, triazines, metallocenes, polycarboxylic acids, hexaaryl bisimidazoles, and borate salts. Of these compositions, the IR-sensitive compositions are preferred.

Such elements include initiator compositions that are appropriate for the desired imaging wavelength(s). More typically, they are responsive to either UV (or “violet”) radiation at a wavelength of from about 150 to about 475 nm (or from about 300 to about 450 nm) or to infrared radiation of at least 700 nm and up to and including 1400 nm.

In general, suitable initiator compositions comprise initiators that include but are not limited to, amines (such as alkanol amines), thiol compounds, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, trihalogenomethyl-arylsulfones, benzoin ethers and esters, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), trihalomethyl substituted triazines, boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). For “violet”-sensitive compositions, the initiators are hexaarylbiimidazoles, oxime esters, or trihalomethyl substituted triazines.

In some embodiments, the radiation-sensitive composition contains a UV sensitizer where the free-radical generating compound is UV radiation sensitive (that is at least 150 nm and up to and including 475 nm), thereby facilitating photopolymerization. In some other embodiments, the radiation sensitive compositions are sensitized to “violet” radiation in the range of at least 300 nm and up to and including 450 nm. Useful sensitizers for such compositions include certain pyrilium and thiopyrilium dyes and 3-ketocoumarins. Some other useful sensitizers for such spectral sensitivity are described for example, in U.S. Pat. No. 6,908,726 (Korionoff et al.), WO 2004/074929 (Baumann et al.) that describes useful bisoxazole derivatives and analogues, and U.S. Patent Application Publications 2006/0063101 and 2006/0234155 (both Baumann et al.).

Still other useful sensitizers are the oligomeric or polymeric compounds having Structure (I) units defined in WO 2006/053689 (Strehmel et al.) that have a suitable aromatic or heteroaromatic unit that provides a conjugated π-system between two heteroatoms.

Additional useful “violet”-visible radiation sensitizers are the compounds described in WO 2004/074929 (Baumann et al.). These compounds comprise the same or different aromatic heterocyclic groups connected with a spacer moiety that comprises at least one carbon-carbon double bond that is conjugated to the aromatic heterocyclic groups, and are represented in more detail by Formula (I) of the noted publication.

Some useful negative-working imageable compositions and elements with which the present invention can be used include but are not limited to, those described in EP Patent Publications 770,494A1 (Vermeersch et al.), 924,570A1 (Fujimaki et al.), 1,063,103A1 (Uesugi), EP 1,182,033A1 (Fujimako et al.), EP 1,342,568A1 (Vermeersch et al.), EP 1,449,650A1 (Goto), and EP 1,614,539A1 (Vermeersch et al.), U.S. Pat. No. 4,511,645 (Koike et al.), U.S. Pat. No. 6,027,857 (Teng), U.S. Pat. No. 6,309,792 (Hauck et al.), U.S. Pat. No. 6,569,603 (Furukawa et al.), U.S. Pat. No. 7,045,271 (Tao et al.), U.S. Pat. No. 7,049,046 (Tao et al.), U.S. Pat. No. 7,169,334 (Baumann et al.), U.S. Pat. No. 7,175,969 (Ray et al.), U.S. Pat. No. 7,183,039 (Timpe et al.), U.S. Pat. No. 7,279,255 (Tao et al.), U.S. Pat. No. 7,285,372 (Baumann et al.), U.S. Pat. No. 7,291,438 (Sakurai et al.), U.S. Pat. No. 7,326,521 (Tao et al.), U.S. Pat. No. 7,332,253 (Tao et al.), U.S. Pat. No. 7,442,486 (Baumann et al.), and U.S. Pat. No. 7,452,638 (Yu et al.), and U.S. Patent Application Publications 2003/0064318 (Huang et al.), 2004/0265736 (Aoshima et al.), 2005/0266349 (Van Damme et al.), and 2006/0019200 (Vermeersch et al.). Other negative-working compositions and elements are described for example in Japanese Kokai 2000-187322 (Takasaki), 2001-330946 (Saito et al.), 2002-040631 (Sakurai et al.), 2002-341536 (Miyamoto et al.), and 2006-317716 (Hayashi).

The imageable elements processed using the invention can also be single- or multi-layer, thermally-sensitive, positive-working imageable elements that generally rely on a radiation absorbing compound dispersed within one or more polymeric binders that, upon suitable irradiation, are soluble, dispersible, or removable in alkaline developers. Thus, the imageable layer, upon irradiation, undergoes a change in solubility properties with respect to the alkaline solution in its irradiated (exposed) regions.

For example, “single-layer” positive-working imageable elements are described for example, in WO 2004/081662 (Memetea et al.), U.S. Pat. No. 6,255,033 (Levanon et al.), U.S. Pat. No. 6,280,899 (Hoare et al.), U.S. Pat. No. 6,485,890 (Hoare et al.), U.S. Pat. No. 6,558,869 (Hearson et al.), U.S. Pat. No. 6,706,466 (Parsons et al.), U.S. Pat. No. 6,541,181 (Levanon et al.), U.S. Pat. No. 7,223,506 (Kitson et al.), U.S. Pat. No. 7,247,418 (Saraiya et al.), U.S. Pat. No. 7,270,930 (Hauck et al.), U.S. Pat. No. 7,279,263 (Goodin), and U.S. Pat. No. 7,399,576 (Lavenon), EP 1,627,732 (Hatanaka et al.), and U.S. Published Patent Applications 2005/0214677 (Nagashima), 2004/0013965 (Memetea et al.), 2005/0003296 (Memetea et al.), and 2005/0214678 (Nagashima).

Other imageable elements that comprise an aluminum-containing substrate (provided according to this invention), an inner layer (also known as an “underlayer”), and an ink-receptive outer layer (also known as a “top layer” or “topcoat”) disposed over the inner layer. Before thermal imaging, the outer layer is generally not soluble, dispersible, or removable by the developer solution within the usual time allotted for development, but after thermal imaging, the imaged regions of the outer layer are more readily removable by or dissolvable in the developer solution. The inner layer is also generally removable by the developer solution. An infrared radiation absorbing compound (defined below) is also present in the imageable element, and is typically present in the inner layer but may optionally be in a separate layer between the inner and outer layers.

Thermally imageable, multi-layer elements are described, for example, in U.S. Pat. No. 6,294,311 (Shimazu et al.), U.S. Pat. No. 6,352,812 (Shimazu et al.), U.S. Pat. No. 6,593,055 (Shimazu et al.), U.S. Pat. No. 6,352,811 (Patel et al.), U.S. Pat. No. 6,358,669 (Savariar-Hauck et al.), U.S. Pat. No. 6,528,228 (Savariar-Hauck et al.), U.S. Pat. No. 7,163,770 (Saraiya et al.), U.S. Pat. No. 7,163,777 (Ray et al.), U.S. Pat. No. 7,186,482 (Kitson et al.), U.S. Pat. No. 7,223,506 (noted above), U.S. Pat. No. 7,229,744 (Patel), U.S. Pat. No. 7,241,556 (Saraiya et al.), U.S. Pat. No. 7,247,418 (noted above), U.S. Pat. No. 7,291,440 (Ray et al.), U.S. Pat. No. 7,300,726 (Patel et al.), and U.S. Pat. No. 7,338,745 (Ray et al.), U.S. Patent Application Publications 2004/0067432 A1 (Kitson et al.) and 2005/0037280 (Loccufier et al.).

The inner layer is disposed between the outer layer and the substrate. Typically, it is disposed directly on the substrate. The inner layer comprises a predominant first polymeric material that is removable by the developer composition and preferably soluble in the developer composition to reduce sludging. In addition, this first polymeric material is preferably insoluble in the solvent used to coat the outer layer so that the outer layer can be coated over the inner layer without dissolving the inner layer. Mixtures of these first polymeric binders can be used if desired in the inner layer.

Useful first polymeric binders for the inner layer include but are not limited to, (meth)acrylonitrile polymers, (meth)acrylic resins comprising pendant carboxy groups, polyvinyl acetals, maleated wood rosins, styrene-maleic anhydride copolymers, (meth)acrylamide polymers such as polymers derived from N-alkoxyalkyl methacrylamide, polymers derived from an N-substituted cyclic imide, polymers having pendant urea or cyclic urea groups, and combinations thereof. First polymeric binders that provide resistance both to fountain solution and aggressive washes are disclosed in U.S. Pat. No. 6,294,311 (noted above).

Useful first polymeric binders include (meth)acrylonitrile polymers, and polymers derived from an N-substituted cyclic imide (especially N-phenylmaleimide), a (meth)acrylamide (especially methacrylamide), a monomer having a pendant urea or cyclic urea group, and a (meth)acrylic acid (especially methacrylic acid). First polymeric binders of this type are copolymers that comprise from about 20 to about 75 mol % of recurring units derived from N-phenylmaleimide, N-cyclohexylmaleimide, N-(4-carboxyphenyl)maleimide, N-benzylmaleimide, or a mixture thereof, from about 10 to about 50 mol % of recurring units derived from acrylamide, methacrylamide, or a mixture thereof, and from about 5 to about 30 mol % of recurring units derived from methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid. Optionally, these polymers can also include recurring units derived from (meth)acrylonitrile or N-[2-(2-oxo-1-imidazolidinyl)ethyl]-methacrylamide.

Other useful first polymeric binders can comprise, in polymerized form, from about 5 mol % to about 30 mol % of recurring units derived from an ethylenically unsaturated polymerizable monomer having a carboxy group (such as acrylic acid, methacrylic acid, itaconic acid, and other similar monomers known in the art (acrylic acid and methacrylic acid are preferred), from about 20 mol % to about 75 mol % of recurring units derived from N-phenylmaleimide, N-cyclohexylmaleimide, or a mixture thereof, optionally, from about 5 mol % to about 50 mol % of recurring units derived from methacrylamide, and from about 3 mol % to about 50 mol % of one or more recurring units derived from monomer compounds of the following Structure (I):

CH₂═C(R₂)—C(═O)—NH—CH₂—OR, (I)

wherein R₁ is a C₁ to C₁₂ alkyl, phenyl, C₁ to C₁₂ substituted phenyl, C₁ to C₁₂ aralkyl, or Si(CH₃)₃, and R₂ is hydrogen or methyl. Methods of preparation of certain of these polymeric materials are disclosed in U.S. Pat. No. 6,475,692 (Jarek).

In some embodiments, the inner layer (and typically only the inner layer) further comprises an infrared radiation absorbing compound (“IR absorbing compounds”) that absorbs radiation from about at 600 nm to about 1500 and typically from about at 700 nm to about 1200 nm, with minimal absorption at from about 300 to about 600 nm. This compound (sometimes known as a “photothermal conversion material”) absorbs radiation and converts it to heat. Although one of the polymeric materials may itself comprise an IR absorbing moiety, typically the infrared radiation absorbing compound is a separate compound. This compound may be either a dye or pigments such as iron oxides and carbon blacks. Examples of useful pigments are ProJet 900, ProJet 860 and ProJet 830 (all available from the Zeneca Corporation).

Useful infrared radiation absorbing compounds also include carbon blacks including carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful.

IR absorbing dyes (especially those that are soluble in an alkaline developer) are desired to prevent sludging of the developer by insoluble material. Examples of suitable IR dyes include but are not limited to, azo dyes, squarilium dyes, croconate dyes, triarylamine dyes, thioazolium dyes, indolium dyes, oxonol dyes, oxaxolium dyes, cyanine dyes, merocyanine dyes, phthalocyanine dyes, indocyanine dyes, indoaniline dyes, merostyryl dyes, indotricarbocyanine dyes, oxatricarbocyanine dyes, thiocyanine dyes, thiatricarbocyanine dyes, cryptocyanine dyes, naphthalocyanine dyes, polyaniline dyes, polypyrrole dyes, polythiophene dyes, chalcogenopyryloarylidene and bi(chalcogenopyrylo) polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, squarine dyes, oxazole dyes, croconine dyes, porphyrin dyes, and any substituted or ionic form of the preceding dye classes. Suitable dyes are also described in numerous publications including U.S. Pat. No. 6,294,311 (noted above) and U.S. Pat. No. 5,208,135 (Patel et al.) and the references cited thereon.

Examples of useful IR absorbing compounds include ADS-830A and ADS-1064 (American Dye Source, Baie D'Urfe, Quebec, Canada), EC2117 (FEW, Wolfen, Germany), Cyasorb® IR 99 and Cyasorb® IR 165 (GPTGlendale Inc. Lakeland, Fla.), and IR Absorbing Dye A used in the Examples below.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanabe et al.). Suitable dyes may be formed using conventional methods and starting materials or obtained from various commercial sources including American Dye Source (Canada) and FEW Chemicals (Germany). Other useful dyes for near infrared diode laser beams are described, for example, in U.S. Pat. No. 4,973,572 (DeBoer).

In addition to low molecular weight IR-absorbing dyes, IR dye moieties bonded to polymers can be used as well. Moreover, IR dye cations can be used, that is, the cation is the IR absorbing portion of the dye salt that ionically interacts with a polymer comprising carboxy, sulfo, phosphor, or phosphono groups in the side chains.

The infrared radiation absorbing compound can be present in the imageable element in an amount of generally from about 5% to about 30% and typically from about 12 to about 25%, based on the total dry weight of the element. This amount is based on the total dry weight of the layer in which it is located.

The ink-receptive outer layer of the imageable element is disposed over the inner layer and in typical embodiments there are no intermediate layers between the inner and outer layers. The outer layer comprises a polymeric material that is different than the first polymeric binder described above. The outer layer is substantially free of infrared radiation absorbing compounds, meaning that none of these compounds are purposely incorporated therein and insubstantial amounts diffuse into it from other layers.

Thus, the outer layer comprises a polymeric binder that is a light-stable, water-insoluble, alkaline developer soluble, film-forming binder material such as phenolic resins, urethane resins, and polyacrylates. Particularly useful binder materials are described, for example in U.S. Pat. No. 6,352,812 (noted above), U.S. Pat. No. 6,358,669 (noted above), U.S. Pat. No. 6,352,811 (noted above), U.S. Pat. No. 6,294,311 (noted above), U.S. Pat. No. 6,893,783 (Kitson et al.), and U.S. Pat. No. 6,645,689 (Jarek), U.S. Patent Application Publications 2003/0108817 (Patel et al) and 2003/0162126 (Kitson et al.), and WO 2005/018934 (Kitson et al.).

Other useful film-forming polymeric binders for the outer layer are phenolic resins or hydroxy-containing polymers containing phenolic monomeric units that can be random, alternating, block, or graft copolymers of different monomers and may be selected from polymers of vinyl phenol, novolak resins, or resole resins.

Useful poly(vinyl phenol) resins can be polymers of one or more hydroxyphenyl containing monomers such as hydroxystyrenes and hydroxyphenyl (meth)acrylates. Other monomers not containing hydroxy groups can be copolymerized with the hydroxy-containing monomers. These resins can be prepared by polymerizing one or more of the monomers in the presence of a radical initiator or a cationic polymerization initiator using known reaction conditions.

Examples of useful hydroxy-containing polymers include ALNOVOL SPN452, SPN400, HPN100 (Clariant GmbH), DURITE PD443, SD423A, SD126A, PD494A, PD-140 (Hexion Specialty Chemicals, Columbus, Ohio), BAKELITE 6866LB02, AG, 6866LB03 (Bakelite AG), KR 400/8 (Koyo Chemicals Inc.), HRJ 1085 and 2606 (Schenectady International, Inc.), and Lyncur CMM (Siber Hegner), all of which are described in U.S. Patent Application Publication 2005/0037280 (noted above).

Useful novolak resins in the upper layer can be non-functionalized, or functionalized with polar groups including but not limited to, diazo groups, carboxylic acid esters (such as acetate benzoate), phosphate esters, sulfinate esters, sulfonate esters (such as methyl sulfonate, phenyl sulfonate, tosylate, 2-nitrobenzene tosylate, and p-bromophenyl sulfonate), and ethers (such as phenyl ethers). The phenolic hydroxyl groups can be converted to -T-Z groups in which “T” is a polar group and “Z” is another non-diazide functional group (as described for example in WO 99/01795 of McCullough et al. and U.S. Pat. No. 6,218,083 of McCullough et al.). The phenolic hydroxyl groups can also be derivatized with diazo groups containing o-naphthoquinone diazide moieties (as described for example in U.S. Pat. Nos. 5,705,308 and 5,705,322 both of West et al.).

Useful polymeric binders in the outer layer include copolymers comprising recurring units derived from styrene or a styrene derivative and recurring units derived from maleic anhydride, copolymers comprising recurring units derived from a (meth)acrylate and recurring units derived from a (meth)acrylic acid, or mixtures of both types of copolymers. Further details of these types of copolymers are described in U.S. Patent Application Publication 2007/0065737 (Kitson et al.).

The outer layer can also include non-phenolic polymeric materials as film-forming binder materials in addition to or instead of the phenolic resins described above. Such non-phenolic polymeric materials include polymers formed from maleic anhydride and one or more styrenic monomers (that is styrene and styrene derivatives having various substituents on the benzene ring), polymers formed from methyl methacrylate and one or more carboxy-containing monomers, and mixtures thereof. These polymers can comprises recurring units derived from the noted monomers as well as recurring units derived from additional, but optional monomers [such as (meth)acrylates, (meth)acrylonitriles and (meth)acrylamides].

In some embodiments, the outer layer may further include a monomeric or polymeric compound that includes a benzoquinone diazide or naphthoquinone diazide moiety. The polymeric compounds can be phenolic resins derivatized with a benzoquinone diazide or naphthoquinone diazide moiety as described for example in U.S. Pat. No. 5,705,308 (West et al.) and U.S. Pat. No. 5,705,322 (West et al.). Mixtures of such compounds can also be used. An example of a useful polymeric compound of this type is P-3000, a naphthoquinone diazide of a pyrogallol/acetone resin (available from PCAS, France). Other useful compounds containing diazide moieties are described for example in U.S. Pat. No. 6,294,311 (noted above) and U.S. Pat. No. 5,143,816 (Mizutani et al.).

The outer layer can optionally include additional compounds that are colorants that may function as solubility-suppressing components for the alkali-soluble polymers. These colorants typically have polar functional groups that are believed to act as acceptor sites for hydrogen bonding with various groups in the polymeric binders. Colorants that are soluble in the alkaline developer are preferred. Useful polar groups include but are not limited to, diazo groups, diazonium groups, keto groups, sulfonic acid ester groups, phosphate ester groups, triarylmethane groups, onium groups (such as sulfonium, iodonium, and phosphonium groups), groups in which a nitrogen atom is incorporated into a heterocyclic ring, and groups that contain a positively charged atom (such as quaternized ammonium group). Further details and representative colorants are described for example in U.S. Pat. No. 6,294,311 (noted above). Particularly useful colorants include triarylmethane dyes such as ethyl violet, crystal violet, malachite green, brilliant green, Victoria blue B, Victoria blue R, and Victoria pure blue BO. These compounds can act as contrast dyes.

### Imaging and Development

A lithographic printing plate precursor is exposed to a suitable source of radiation, including UV, visible and infrared radiation using a suitable source. As noted above, “analog” precursors can be imaged using suitable UV or visible actinic radiation through a suitable imaged graphic arts film. The imaged precursor is then processed using the developer solution of this invention as described below.

For thermally-sensitive lithographic printing plate precursors, it is desired to irradiate using an infrared laser at a wavelength of from about 300 nm to about 1500 nm and typically at a wavelength of from about 700 nm to about 1200 nm. The lasers used to expose the imageable elements are typically diode lasers, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 850 nm or from about 1040 to about 1120 nm.

The imaging apparatus can be configured as a flatbed recorder or as a drum recorder, with the imageable member mounted to the interior or exterior cylindrical surface of the drum. Examples of useful imaging apparatus are available as models of Kodak® Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio). Imaging is generally carried out by direct digital imaging (that is, “computer-to-plate” imaging).

The thermally imaged element comprises a latent image of imaged (exposed) and non-imaged (non-exposed) regions.

For imaged positive-working lithographic printing plate precursors, development removes the exposed regions of one or more layers, for example, the outer layer and the underlying layers (including the inner layer), and exposes the hydrophilic surface of the substrate of this invention. The exposed (or imaged) regions of the hydrophilic surface of the substrate repel ink while the non-exposed (or non-imaged) regions of the outer layer accept ink. For imaged negative-working lithographic printing plate precursors, the non-imaged regions are removed while the imaged regions are hardened and accept ink.

Generally, development of the imaged element can be carried out by rubbing or wiping its outermost layer with an applicator containing the developer solution. Alternatively, the imaged element can be brushed with the developer solution, or the developer solution can be applied by spraying the imaged element with sufficient force to remove the appropriate regions. In still another alternative, the imaged element can be immersed in the developer solution in a suitable reservoir.

Thus, the development process can be carried out using equipment having the appropriate arrangement of tanks, spray bars, plumbing, rollers, pumps, or applicators. Commercially available “spray on” processors include the 85 NS Processor (Eastman Kodak Company, Norwalk, Conn.). Commercially available “immersion” processors include the Mercury™ Mark V Processor (Eastman Kodak Company), the Global Graphics Titanium Processor (Global Graphics, Trenton, N.J.) and the Glunz and Jensen Quartz 85 Processor (Glunz and Jensen, Elkwood, Vs.).

Generally, the imaged elements are developed using the developer solution of this invention at from about 19 to about 25° C. for from about 5 to about 60 seconds (residence time).

During development, the developer solution can be replenished with a developer replenisher that has substantially the same pH, chemical composition, and activity as the developer solution. Alternatively, the developer concentrate can be metered into the developer solution, with or without additional water. Replenishment can be carried out at any particularly useful rate, and either continuously or intermittently, using conventional conditions and equipment.

Following development, the lithographic printing plate can be rinsed with water and dried in a suitable fashion. The dried printing plate can also be treated with a conventional gumming solution (preferably a surfactant, starch, dextrin, or gum Arabic desensitizing solution).

The lithographic printing plate can also be baked to increase run length of the resulting imaged element. Baking can be carried out, for example at a temperature of from about 220° C. to about 240° C. for a time of from about 7 to about 10 minutes, or at about 120° C. for 30 minutes.

A lithographic ink and fountain solution can be applied to the printing surface of the printing plate for printing. Ink is taken up by the oleophilic regions of the outer layer and the fountain solution is taken up by the hydrophilic surface (usually the aluminum-containing substrate of this invention) revealed by the imaging and development process. The ink is then transferred to a suitable receiving material (such as cloth, paper, metal, glass, or plastic) to provide a desired impression of the image thereon. An intermediate cylinder is often used to transfer the ink from the printing plate to the receiving material.

The following examples are presented to illustrate the practice of this invention and are not intended to be limiting in any way.

### EXAMPLES

A standard “extreme” concentrate composition was made to contain:

| | |
|---|---|
| Petro AA - 50% | 500 grams |
| Benzyl Alcohol | 400 grams |
| Diethanolamine - 85% | 100 grams |

This standard developer concentrate contained water only from the raw materials, that is, no extra water was added. The water content of the standard developer was 250 grams from the Petro AA plus 15 grams from the diethanolamine or 265 grams (26.5 percent).

To 18 grams of this standard developer concentrate, one gram of the experimental surfactant was added. This is equivalent to 55.6 grams of the surfactant added to 1000 grams of the standard developer concentrate. Some surfactants contain water, and therefore modified the water content of the experimental surfactant solution slightly when compared to the standard developer concentrate.

The surfactant, Petro AA was used in several ready-to-use developer solutions and regenerators made from the concentrates as outlined in TABLE I below. This surfactant forms a stable concentrate, that is, it does not form a haze or precipitate in the concentrated form. However the developer concentrate made with Petro AA formed a haze upon dilution greater than 1:5 (one part concentrate to five parts water). The addition of another alkyl naphthalene sulfonate (Naxan® ABP) in an attempt to improve the haze upon dilution was not successful.

All six inventive surfactants used in the Examples below, when added to the standard developer concentrate provided a stable developer concentrate that could be diluted infinitely with water to form essentially a clear solution with very little or no haze or precipitate.

### Comparative Example 1

### Comparison of Alkyl Naphthalene Sulfonates

The use of Pelex NB-L was compared to the use of Petro AA (Akzo Nobel Ind. Specialists, Houston, Tex.) for concentrate stability and dilutability. The data are presented in the following TABLE I.

TABLE I
Mixtures of Petro AA and Pelex NB-L

| | 3 B | 3 C | 3 D | 3 A | 3 E | 3 F | 3 G |
|---|---|---|---|---|---|---|---|
| | 100:0 | 80:20 | 60:40 | 50:50 | 40:60 | 20:80 | 0:100 |
| Concentrate Formulae - Grams | | | | | | | |
| Pelex NB-L - 35% | 485 | 388 | 291 | 242 | 194 | 97 | |
| Petro AA - 50% | | 97 | 194 | 242 | 291 | 388 | 485 |
| Benzyl Alcohol | 435 | 435 | 435 | 436 | 435 | 435 | 435 |
| Diethanolamine - 85% | 80 | 80 | 80 | 80 | 80 | 80 | 80 |
| | 1000 | 1000 | 1000 | 1000 | 1000 | 1000 | 1000 |
| Precipitate - Concentrate | Heavy | Moderate | Slight- | Slight- | Slight | Slight | None |
| | | | Moderate | Moderate | | | |
| Haze | | | | | | | |
| 1:9 Dilution | Clear | Clear | Clear | Very, | Moderate | Severe | Severe |
| | | | | very slight | | | |
| 1:4 Dilution | Clear | Clear | Clear | Clear | Clear | Clear | Clear |
| 1:2 Dilution | Clear | Clear | Clear | Clear | Clear | Clear | Clear |
| 1:1 Dilution | Clear | Clear | Clear | Clear | Clear | Clear | Clear |

Concentrate 3B was made with only Pelex NB-L. The resulting extreme concentrated solution formed a heavy precipitate after standing for one week at room temperature. However, all dilutions of the concentrated solution formed clear solutions without haze or separation.

Concentrate 3G was made exclusively with Petro AA. The resulting extreme concentrated solution was stable after standing for one week (and remained clear for at least four months). Although the 1:1, 1:2 and 1:4 dilutions of the concentrated solution were clear solutions, the 1:9 dilution produced a severe haze and separation of the solution into phases.

Mixtures of Pelex AA and Petro NB-L showed that all solutions with Pelex AA had precipitates in the concentrated solutions. At concentrations of Pelex AA of 60% and greater, the dilution to 1:9 produced a clear solution.

There was no concentrated solution using Pelex AA, Petro NB-L or mixtures of the two that provided solutions that were acceptable for all solution stability test conditions.

### Invention Example 1

### Surfactant Blends with Petro AA

Various surfactants were blended with a standard Petro AA extreme concentrated solution in an attempt to improve the dilutability without interfering with the good concentrate stability.

Five surfactants were mixed at 5.26% of the final surfactant solution (the actual surfactant concentration would be the use amount times the concentration of the surfactant, for example for Monateric™ CEM-35 the actual surfactant concentration in the mixture would be 5.25×0.35=1.84%) and provided improved concentration stability versus Pelex NB-L alone and gave essentially infinite dilutability. They were Genepol C-200 nonionic emulsifier, Lugalvan® BNO 12, Alkpo LF2, Calsuds® CD-6 coconut oil alkanolamide, and Lugalvan® BNO 24. Although the Pluronic® L64 had a moderate precipitate in the concentrate (that was an improvement over the Pelex AA solution in Comparative Example 1) and provided essentially infinite dilutability, it was in a category separate from the other five preferred surfactants. The concentrated formulae and results are shown in the following TABLE II.

TABLE II

Formulae

| Concentrated Formulae - Grams | W 015-1 A | W 015-1 A |
|---|---|---|
| Petro AA - 50% | 500.0 | 500.0 |
| Benzyl Alcohol | 400.0 | 400.0 |
| Diethanolamine - 85% | 100.0 | 100.0 |
| Formula A | 18.0 | 18.0 |
| Surfactant X below | 1.0 | 1.0 |
| | | Water |
| | | Diluted |
| | | Concentrate |
| | | Two Grams |

| | | | | Calculated |
|---|---|---|---|---|
| | | Concentrate | Haze | Possible |
| Surfactant X Name | Surfactant | Precipitate | Total Wt. (g) | Dilution |
| Checks - See Comparative Example 1 | Conc. (%) | 7 Days | Water | (Developer:water) |
| Petro AA - No addition | 50.0 | No | 17 | 1:8.4 |
| Pelex NB-L - No addition | 35.0 | Moderate | 100 | 1:50+ |
| Pluronic ® L81 | 99.9 | — | 5 | 1:2.6 |
| Tween ® 20 | 100.0 | — | 11 | 1:5.7 |
| Cola ® Teric MSC-Na | 100.0 | — | 12 | 1:6.1 |
| Naxonate ® ST | 97.6 | — | 17 | 1:8.4 |
| Naxonate ® SX | 96.7 | — | 17 | 1:8.6 |
| Naxonate ® SMS | 91.1 | — | 18 | 1:8.9 |
| Sodium Xylene Sulfonate | 100.0 | — | 18 | 1:9.2 |
| Monacor BE | 100.0 | — | 19 | 1:9.7 |
| Naxan ® ABP | 96.7 | Heavy | 20 | 1:10.0 |
| Monateric ™ CEM 38 | 38.0 | — | 22 | 1:10.8 |
| Pluronic ® L64 | 99.9 | Moderate | 88 | 1:50+ |
| Genapol C-200 | 100.0 | None | 100 | 1:50+ |
| Lugalvan ® BNO 12 | 99.8 | None | 100 | 1:50+ |
| Alkpo LF2-US | 92.0 | None | 101 | 1:50+ |
| Calsuds ® CD-6 | 100.0 | Very, very slight | 108 | 1:50+ |
| Lugalvan ® BNO 24 | 75.3 | None | 122 | 1:50+ |

Generally the surfactants evaluated were in concentrated form. Many were powders. The Monateric™ CEM 38 was an exception.

### Invention Examples 2-6

### Digital Plates Processed with Diluted Extreme Concentrated Solution W 015-10F

TABLE III

| | Formulae |
|---|---|
| | W 015-10 F |
| Concentrated Formulae - Grams | Check 2 |
| Petro AA - 50% | 400.0 |
| Lugalvan ® BNO 24 | 100.0 |
| Benzyl Alcohol | 400.0 |
| Diethanolamine - 85% | 100.0 |
| | 1000.0 |
| pH | 11.9 |
| Conductivity | 3433 mS |
| Appearance - Four Days Later | |
| Concentrate | Clear |
| 1:4 Dilution | Clear |
| 1:9 Dilution | Clear |

Formula W 015-10F was made as described in TABLE III above. The extreme concentrated solution was diluted as indicated in TABLE IV below and five commercially available and imaged printing plates were hand processed by swabbing the developer across the plate surface for thirty seconds, rinsed, and dried. At the preferred dilution, all of the printing plates had high Dₘₐₓ values indicating very little or no image loss. Examination of the printing plate backgrounds showed that no residual image was present.

The dilutions of the W 015-10F formula were clear or no more than a very slight haze was observed in the intermediate dilutions. The presence of the very slight haze did not detract from the developer performance, but a precipitate and phase separation would in fact impact performance.

The thermal imageable elements described in TABLE IV below were imagewise exposed using a Kodak® Trendsetter image setter and the violet-sensitive imageable element was imagewise exposed using a FUJI Luxel 9600 imaging device. Exposures and preheat temperatures are outlined in TABLE IV. After exposure, the imaged elements were evaluated both visually and using densitometry. Dₘₐₓ and Dₘᵢₙ were measured using an X-Rite 418 and dot sizes on the printing plates were measured using an iC plate II densitometer.

TABLE IV

| | Example 2 | Example 3 | Example 4 | | Example 6 |
|---|---|---|---|---|---|
| | SWORD | THERMAL | Thermal | Example 5 | THERMAL |
| Imageable Elements | EXCEL | NEWS GOLD | Direct* | Violet | GOLD |
| Positive/Negative | Positive | Negative | Negative | Negative | Negative |
| Layers | 2 | 1 | 1 | 2 | 1 |
| Developer | W 015-10F | W 015-10F | W 015-10F | W 015-10F | W 015-10F |
| Optimum Dilution | 1:9 | 1:25 | 1:80 | 1:30 | 1:6 |
| pH - Diluted | 10.9 | 10.7 | 10.3 | 10.6 | 11.2 |
| Conductivity - Diluted | 4726 mS | 2317 mS | 859 mS | 2172 mS | 6174 mS |
| Exposure - mJ/cm² | 120 | 76 | 325 | 39 μJ/cm² | 105 |
| Oven Temperature (° C.) | — | 129 | — | 123 | 118 |
| Appearance - Diluted | Clear | Very slight haze | Clear | Very, very slight haze | Clear |
| Dₘₐₓ | 1.00 | 1.01 | 0.35 | 0.97 | 0.91 |
| Dₘᵢₙ | 0.32 | 0.29 | 0.24 | 0.30 | 0.32 |
| Cleanout - Seconds | 4/10/30 | 11/30 | 9/30 | 8/30 | 33/30**** |
| Dots - AM | | | | | |
| 2% | 1.6 | 2.4 | 2.9 | 1.5 | 1.6 |
| 10% | 8.5 | 10.6 | 9.8 | 6.4 | 8.6 |
| 50% | 49.8 | 53.6 | 68.6*** | 51.3 | 49.4 |
| 90% | 90.4 | 91.6 | —** | 94.3 | 90.0 |
| 98% | 97.4 | 98.3 | —** | 99.6 | 97.6 |
| Dots - FM 20 | | | | | |
| 2% | 1.5 | 2.2 | — | — | 1.9 |
| 10% | 7.5 | 11.1 | — | — | 9.0 |
| 50% | 50.5 | 57.4 | — | — | 48.1 |
| 90% | 89.1 | 92.8 | — | — | 90.6 |
| 98% | 97.8 | 98.4 | — | — | 98.2 |
| Dots - FM 10 | | | | | |
| 2% | 1.5 | 2.3 | — | — | 2.4 |
| 10% | 4.8 | 11.4 | — | — | 8.0 |
| 50% | 55.9 | 60.5 | — | — | 45.7 |
| 90% | 95.8 | 94.9 | — | — | 96.8 |
| 98% | 98.2 | 99.2 | — | — | 99.2 |

*No standard process for this plate - it is direct to press.
**Densitometer unable to read dots because of low density.
***Check dots were 67.2.
****MX 1813 check developer was also 33 seconds cleanout.

All of the imaged elements were processed easily yielding results very similar to printing plates processed with the appropriate production ready-to-use developer. The formulations of the production ready-to-use developers varied greatly both in concentration and materials in the composition, while the extreme concentrated developers were based on a single formula.

### Invention Examples 7-8

### Sword J Digital Plate—Optimal Performance at 1:15 to 1:18 Dilution of the Extreme Concentrated Solution (W 015-10F)

For Example 7, a commercially available Kodak SWORD J thermal printing plate (a two layer positive-working plate available from Kodak Graphic Communications Japan LTD) was imagewise exposed using a Kodak® Trendsetter 800 II Quantum plate setter. Test pattern ‘Plot 5’ was applied to the plate at an energy of 100 mJ/cm². Developer drop tests were performed using W015-10F at various dilutions using water. Drops of developer were applied to exposed and unexposed areas of the surface at 10 second intervals up to 180 seconds and then rinsed away with water. The time needed for the developer to dissolve the coating in the exposed areas was recorded. The time needed to see initial developer attack on the unexposed areas was also recorded. The following developer drop tests (TABLE V) were observed at various developer dilutions.

TABLE V

| WO15-10F to | Time to dissolve the | | Time to see initial attack |
|---|---|---|---|
| Water Ratio | exposed areas | | on the unexposed areas |
| 1 to 12 | <10 | seconds | 50 seconds |
| 1 to 15 | <10 | seconds | 150 seconds |
| 1 to 18 | <10 | seconds | >180 seconds |
| 1 to 24 | 10-20 | seconds | >180 seconds |

The drop test results suggest that excellent image contrast was obtained over a wide range of concentrated developer dilutions.

For Example 8, a commercial Kodak Sword J thermal printing was imagewise exposed using a Kodak® Trendsetter 800 II Quantum plate setter. Test pattern ‘Plot 0’ was applied to the element at energies of 60, 63, 67, 71, 76, 82, 88, 96, 105, 116, 130, and 147 mJ/cm².

A developer provided from W015-10F (1 part) and water (15 parts) was placed in a tray at room temperature (˜23° C.). The imaged element was immersed in the developer for 15 seconds, swabbed lightly for 5 seconds, and then rinsed thoroughly with water. The minimum energy required to produce a clean image was recorded, as was the energy required to produce optimum image reproduction. The test was then repeated, except that the element was immersed in the developer for 35 seconds and swabbed for 5 seconds before rinsing. The results are shown below in TABLE VI.

TABLE VI

| Total Development | Cleanout | Optimum |
|---|---|---|
| Time | exposure | Exposure |
| 20 seconds | 67 mJ/cm² | 96 mJ/cm² |
| 40 seconds | 67 mJ/cm² | 96 mJ/cm² |

The imaging results suggest that the developer had good latitude and produced a stable image. Doubling the development time did not affect image quality.

### Invention Example 9

### Experimental No Preheat Negative-Working Two Layer Digital Plate—W015-10F (1+8 Dilution)

A no-preheat, negative-working printing plate precursor was prepared using the formulation shown in the following TABLE VII as the imageable layer.

TABLE VII

| Component | mg/m² |
|---|---|
| Copolymer 1 | 175 |
| Hybridur ® 580 | 234 |
| SR 399 | 266 |
| NK-Ester A-DPH | 266 |
| CD9053 | 53 |
| Bis-t-butylphenyliodonium | 96 |
| tetraphenylborate | |
| FluorN 2900 | 11 |
| Pigment 1 | 73 |
| IR Dye 1 | 27 |
| Dry coating weight (mg/m²) | 1200.0 |

The components were coated out of a solvent blend (weight percent) of water, 1-methoxy-2-propanol, 2-butryolactone, and 2-butanone (10/35/10/45). The components are identified below.

The formulation was applied to an electrochemically grained and sulfuric acid anodized aluminum substrate that had been post-treated with an inorganic monosodium phosphate solution activated by sodium fluoride. It was applied using a slotted hopper to yield a dry coating weight of about 1200 mg/m² and dried at about 82° C. for 90 seconds. An oxygen protective topcoat was then applied having a formulation of 398 mg/m² of PVA 405, 2 mg/m² of Masurf® 1520, and water to yield a dry film weight of 400 mg/m² using the same coating techniques.

The resulting negative-working imageable element was imaged on a Kodak® Trendsetter Quantum 800II at 10.3W and an appropriate drum speed at an energy of 75 mj/cm². The imaged element was hand developed for 30 seconds with developer solution W015-10F diluted 9-fold (1+8 dilution) with tap water. The imaged element was easily developed and the non-imaged areas were processed clean. The optical density of the processed background measured 0.329 with a cyan filter in place while the optical density of the uncoated substrate measured 0.326 with the cyan filter. No substrate staining was measureable.

A finishing gum solution, 850 s (from Eastman Kodak Company), was applied to the printing plate and it was then mounted on a Heidelberg Speedmaster 74, one color, sheet-fed printing press charged with black ink containing 1.5% calcium carbonate and fitted with a compressible blanket. The calcium carbonate ink was chosen in order to accelerate the wear of the printing plate, thus artificially shortening plate run length. The fountain solution was Varn 142W etch at 3 oz per gallon (23.4 ml/liter) and PAR alcohol replacement at 3 oz per gallon (23.4 ml/liter). The resulting lithographic printing plate was used to print 55,000 copies before showing wear in the solid image areas.

List of Component Descriptions:
Copolymer 1 is described in U.S. Pat. No. 7,332,253 (Tao et al.) as Polymer A.
Hybridur® 580 is a urethane-acrylic hybrid polymer dispersion (40%) that was obtained from Air Products and Chemicals, Inc. (Allentown, Pa.).
SR 399 is dipentaerythritol pentaacrylate available from Sartomer Company, Inc. (Exton, Pa.).
NK Ester A-DPH is a dipentaerythritol hexaacrylate that was obtained from Kowa American (New York City, N.Y.).
CD 9053 is a trifunctional acid ester from Sartomer Company, Inc. (Exton, Pa.).
FluorN 2900 is a surfactant from Cytonix (Beltsville, Md).
Pigment 1 is a 23% wt solids dispersion of 7.7 parts of a polyvinyl acetal derived from polyvinyl alcohol acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersing aid (from Byk Chemie) in 1-methoxy-2-propanol.
IR Dye 1 is 2-[2-[3-[2-(1,3-Dihydro-1,3,3-trimethyl-2H-indol-2-ylidene)-ethylidene]-2-(1-phenyl-1H-tetrazol-5-ylsulfanyl)-1-cyclohexen-1-yl]-ethenyl]-1,3,3-trimethyl-3H-indolium chloride and it is available from FEW Chemicals (Germany).
PVA-405 is a poly vinyl alcohol available from Kuraray (New York City, N.Y.).
Masurf® FS-1520 is a fluoroaliphatic betaine fluorosurfactant that was obtained from Mason Chemical Company (Arlington Heights, Ill.).

### Invention Example 10

### Experimental No Preheat Negative-Working Two Layer Digital Plate—W015-10F (1:4 Dilution)

The coating formulations described below in TABLE VIII was mixed and coated to produce a dry coating weight of 1.2 g/m² to provide an imageable layer and 0.4 g/m² for the topcoat (oxygen barrier layer) on an anodized aluminum plate. The resulting imageable element was imagewise exposed using a Kodak® CREO trendsetter at 65 mJ/cm².

TABLE VIII

| Imageable Layer | | Topcoat | |
|---|---|---|---|
| Components | Grams Solids | Components | Grams Solids |
| Hybridur ® 580 | 11.400 | PVA-403 | 14.840 |
| ACR-1755 | 8.550 | Masurf ® 1520 | 0.0746 |
| SR-399 | 12.954 | Isopropyl alcohol | 39.403 |
| NK-Ester A-DPH | 12.954 | Water | 945.682 |
| PAM100 | 2.591 | | 1000.000 |
| IB05 | 4.663 | | |
| S0507 | 1.295 | | |
| Pigment 951 | 3.562 | | |
| FlourN 2900 | 0.518 | | |
| PGME | 254.208 | | |
| BLO | 112.981 | | |
| Water | 83.795 | | |
| Methanol | 141.227 | | |
| Methyl ethyl ketone | 349.301 | | |
| | 1000.000 | | |

The exposed imageable plate was processed by swabbing the plate with the test reconstituted developer for 15 seconds, then rinsing and drying. Dₘₐₓ, Dₘᵢₙ, and dot measurements (AM200) were taken as described above and the results are shown in the following TABLE IX.

TABLE IX

| | |
|---|---|
| W 015-29D | W 015-10F |

| | 1 to 2 | 1 to 3 | 1 to 2 | 1 to 3 | 1 to 4 |
|---|---|---|---|---|---|
| Dₘₐₓ | 1.05 | 1.05 | 1.05 | 1.05 | 1.05 |
| Dₘᵢₙ | 0.33 | 0.33 | 0.33 | 0.33 | 0.33 |
| AM200 | | | | | |
| 2.0 | 2.7 | 2.5 | 2.3 | 2.3 | 2.3 |
| 10.0 | 10.6 | 10.5 | 10.1 | 10.2 | 10.3 |
| 50.0 | 52.9 | 52.8 | 52.2 | 52.4 | 52.7 |
| 90.0 | 91.3 | 91.2 | 90.9 | 90.9 | 91.0 |
| 98.0 | 98.5 | 98.2 | 98.3 | 98.3 | 98.4 |
| FM10 | | | | | |
| 2.0 | 2.3 | 2.3 | 2.1 | 2.0 | 2.0 |
| 10.0 | 11.7 | 11.8 | 10.1 | 10.2 | 10.5 |
| 50.0 | 59.1 | 57.5 | 55.7 | 56.2 | 56.5 |
| 90.0 | 95.1 | 94.6 | 93.7 | 93.9 | 94.2 |
| 98.0 | 99.3 | 99.3 | 98.9 | 99.0 | 99.0 |

Developer W 015-29D was identical to the W 015-10F formula except the benzyl alcohol was replaced with 2-phenoxyethanol (Dowanol® EPH).

The results indicate excellent performance over a range of dilutions of two extreme concentrate formulas from 1:2 to 1:4.

### Example 11

### Surfactant Mixtures—Amounts

Developer concentrates were prepared as described below in TABLE X.

TABLE X

| | Formulae | | | | | |
|---|---|---|---|---|---|---|
| | | | | | | W 015-10 F |
| | W 274-18 A | W 274-18 B | W 274-18 C | W 274-18 D | W 274-18 E | Check 2 |
| Petro AA - 50% | 400.0 | 400.0 | 400.0 | 400.0 | 400.0 | 400.0 |
| Lugalvan ® BNO | 75.0 | 60.0 | 50.0 | 40.0 | 30.0 | 100.0 |
| 24 | | | | | | |
| Calsuds ® CD6 | 75.0 | 60.0 | 50.0 | 40.0 | 30.0 | |
| Benzyl Alcohol | 400.0 | 400.0 | 400.0 | 400.0 | 400.0 | 400.0 |
| Diethanolamine - | 50.0 | 80.0 | 100.0 | 120.0 | 140.0 | 100.0 |
| 85% | | | | | | |
| | 1000.0 | 1000.0 | 1000.0 | 1000.0 | 1000.0 | 1000.0 |
| Concentrate | | | | | | |
| 1:19 Dilution | Clear | Clear | Very | Slight | Haze | Slight |
| | | | slight | haze | | haze |
| | | | haze | | | |

Haze was apparent in solutions at 1 part developer concentrate to 19 parts water (the most difficult dilution to achieve without haze) when the total amount of Lugalvan® BNO 24 and Calsuds® CD6 was below 12 weight %. Note that the check at 10 weight % Lugalvan® BNO 24 had more haze than the mixture of both Lugalvan® BNO 24 and Calsuds® CD6 at 10 weight %, slight haze versus very slight haze.

### Example 12

### Surfactant Mixtures—Ratios

Developer concentrates were prepared as follows:

TABLE XI

| | Formulas | | | | | |
|---|---|---|---|---|---|---|
| | | | | | | W 015-10 F |
| | W 274-19 C | W 274-19 B | 274-19 A | W 274-19 D | W 274-19 E | Check 2 |
| Petro AA - 50% | 400.0 | 400.0 | 400.0 | 400.0 | 400.0 | 400.0 |
| Lugalvan ® BNO | 125.0 | 100.0 | 75.0 | 50.0 | 25.0 | 100.0 |
| 24 | | | | | | |
| Calsuds ® CD6 | 25.0 | 50.0 | 75.0 | 100.0 | 125.0 | |
| Benzyl Alcohol | 400.0 | 400.0 | 400.0 | 400.0 | 400.0 | 400.0 |
| Diethanolamine - | 50.0 | 50.0 | 50.0 | 50.0 | 50.0 | 100.0 |
| 85% | | | | | | |
| | 1000.0 | 1000.0 | 1000.0 | 1000.0 | 1000.0 | 1000.0 |
| 1:19 Dilution | Very | Clear | Clear | Clear | Clear | Slight |
| | slight | | | | | haze |
| | haze | | | | | |

For the 1:19 dilutions, at a combined weight percent of 15% of the Lugalvan® BNO 24 and Calsuds® CD6, the concentrate with only 2.5 weight % Calsuds® CD6 still has a very slight haze. The solution was clear at 5 weight % Calsuds® CD6.

### Example 13

### Surfactant Mixtures—Processing Experimental No Preheat Negative-Working Two Layer Digital Plate

The printing plate precursors described in Invention Example 10 were processed as described in Invention Example 2.

TABLE XII

| | Formulas | | | |
|---|---|---|---|---|
| | W 274-19 | W 274-19 | W 274-19 | W 015-10 F |
| | B | A | D | Check 2 |
| Petro AA - 50% | 400.0 | 400.0 | 400.0 | 400.0 |
| Lugalvan ® BNO 24 | 100.0 | 75.0 | 50.0 | 100.0 |
| Calsuds ® CD6 | 50.0 | 75.0 | 100.0 | |
| Benzyl Alcohol | 400.0 | 400.0 | 400.0 | 400.0 |
| Diethanolamine - 85% | 50.0 | 50.0 | 50.0 | 100.0 |
| | 1000.0 | 1000.0 | 1000.0 | 1000.0 |
| pH 1:4 | 10.4 | 10.4 | 10.2 | 11.3 |
| Conductivity 1:4 | 8026 mS | 8197 mS | 8344 mS | 7752 mS |
| Dₘₐₓ | 0.94 | 0.95 | 0.95 | 0.96 |
| Dₘᵢₙ | 0.31 | 0.32 | 0.31 | 0.31 |
| Cleanout - Seconds | 5/30 | 9/30 | 6/30 | 5/30 |
| Dots - AM | | | | |
| 2% | 2.4 | 2.3 | 2.3 | 2.4 |
| 10% | 10.2 | 10.1 | 10.2 | 10.2 |
| 50% | 52.8 | 51.7 | 52.3 | 52.4 |
| 90% | 90.8 | 90.9 | 90.9 | 90.8 |
| 98% | 98.5 | 98.5 | 98.5 | 98.3 |
| Dots - FM 20 | | | | |
| 2% | 2.0 | 2.0 | 2.2 | 2.0 |
| 10% | 10.6 | 10.6 | 10.7 | 10.5 |
| 50% | 54.8 | 54.9 | 54.9 | 54.8 |
| 90% | 91.9 | 91.9 | 91.9 | 91.7 |
| 98% | 98.1 | 98.3 | 98.4 | 98.2 |
| Dots - FM 10 | | | | |
| 2% | 2.2 | 2.2 | 2.2 | 2.0 |
| 10% | 10.7 | 10.8 | 10.7 | 10.6 |
| 50% | 57.3 | 56.9 | 56.9 | 55.6 |
| 90% | 94.9 | 94.3 | 95.1 | 94.6 |
| 98% | 99.3 | 99.3 | 99.3 | 99.2 |

The extreme developer concentrates were diluted to 1 part developer concentrate to 4 parts water to process the plates for 30 seconds at room temperature. All imaged elements were processed in less than 10 seconds and produced printing plates with clean non-imaged areas. This example demonstrates the use of developer concentrates for making lithoplate images with a mixture of two surfactants in addition to the alkyl naphthalene sulfonate.

### Invention Example 14

### Thermal News Gold Digital Plate—Extreme Concentrate with No Alkyl Naphthalene Sulfonate Surfactant—1:3 Dilution

An extreme concentrated solution was made according to the following formula shown in the following TABLE XIII. The composition contained no alkyl naphthalene sulfonate.

TABLE XIII

| Concentrate Formulae - Grams | W 015-10 F |
|---|---|
| Water | 332.0 |
| Lugalvan ® BNO 12 | 400.0 |
| 2-Phenoxyethanol | 68.0 |
| Diethanolamine | 200.0 |
| | 1000.0 |
| Concentrate | Clear |
| 1:3 Dilution | Clear |

A commercially available Thermal News Gold plate (Eastman Kodak Company) was imagewise exposed and machine processed as shown in the following TABLE XIV

TABLE XIV

| | |
|---|---|
| Setup | Newsetter |
| Exposure Energy | 75 mJ/cm² |
| Processor | Mercury News 85 |
| Preheat setting | 485° C. |
| Preheat (on plate) | 125° C. |
| Developer temperature | 23° C. |
| Top up rate | 35 ml/m² |
| Developer brush-speed | 120 rpm |
| Gumming | 850 Finisher |
| Speed | 120 cm/min 23 seconds dip-to- |
| | nip |

The processed printing plate was mounted on a printing press and used to produce 200,000 high quality impressions.

### Invention Examples 15-17

### Processing Negative Analog (Non-Digital) Plates—W 015-10F (1:4 Dilution)

Five commercial negative-working analog printing plates were exposed to ultraviolet light through a conventional graphic arts film negative in a Berkey Ascor exposing frame. The imaged elements were hand processed for 30 seconds as above and the results are listed in the following TABLE XV.

TABLE XV

| | | Vistar | Craftsman | Duplex | KNA 3 |
|---|---|---|---|---|---|
| Analog Plates | Winner | 360 | Elite | Elite | 2996 |
| Positive/Negative | Negative | Negative | Negative | Negative | Negative |
| Layers | 1 | 1 | 1 | 1 | 1 |
| Developer | W 015-10F | W 015-10F | W 015-10F | W 015-10F | W 015-10F |
| Optimum Dilution | 1:4 | 1:4 | 1:4 | 1:4 | 1:4 |
| pH - Diluted | 11.9 | 11.9 | 11.9 | 11.9 | 11.9 |
| Conductivity - Diluted | 3433 mS | 3433 mS | 3433 mS | 3433 mS | 3433 mS |
| Exposure - Units | 45 | 45 | 45 | 45 | 45 |
| Appearance - Diluted | Clear | Clear | Clear | Clear | Clear |
| Dₘₐₓ | 0.83 | 0.50 | 0.84 | 0.92 | 0.83 |
| Dₘᵢₙ | 0.26 | 0.30 | 0.28 | 0.29 | 0.26 |
| T-14 Solid Step | 4 | 7 | 6 | 4 | 4 |
| T-14 Toe Step | 8 | 11 | 13 Long toe | 13 Long toe | 9 |
| Cleanout - Seconds | 4/30 | 8/30 | 4/30 | 4/30 | 4/30 |
| Background cleanliness | Clean | Clean | Clean | Clean | Clean |
| Dots - AM | | | | | |
| 2% | 2.2 | 2.2 | 2.4 | 2.2 | 1.9 |
| 10% | 10.4 | 10.2 | 11.1 | 10.6 | 9.4 |
| 50% | 54.0 | 59.0 | 55.0 | 54.3 | 53.7 |
| 90% | 92.6 | 95.1 | 94.1 | 92.4 | 92.1 |
| 98% | 98.8 | 99.6 | 99.2 | 98.6 | 98.4 |

Although all of the noted commercial printing plates were tested beyond their respective expiration dates, they were processed to yield a clean background. There was no residual polymer or coating remaining in the non-image areas of the printing plates. These examples demonstrate the usefulness of the extreme concentrated solutions of this invention that has been reconstituted (1:4 in this case) to process a variety of non-digital plates at a single dilution.

The invention has been described in detail with particular reference to certain preferred embodiments thereof, but it will be understood that variations and modifications can be effected within the spirit and scope of the invention.

1. A developer concentrate that is free of silicates and alkali hydroxides, and comprises:
a. no more than 60 weight % water,
b. a water-soluble or water-miscible organic solvent,
c. one or more alkyl ether carboxylic acid, coconut oil alkanolamine, coconut fatty alcohol polyglycol ether, β-naphtholethoxylate, and block propylene oxide-ethylene oxide in an amount of at least 0.1 and up to 50 weight % solids, and
d. optionally, an alkyl naphthalene sulfonate in an amount of up to 40 weight % solids.

2. The developer concentrate of claim 1 comprising no more than 40 weight % water.

3. The developer concentrate of claim 1 comprising no more than 30 weight % water.

4. The developer concentrate of claim 1 wherein said water-soluble or water-miscible organic solvent is benzyl alcohol or 2-phenoxyethanol.

5. The developer concentrate of claim 1 further comprising an amine base.

6. The developer concentrate of claim 1 wherein one or more alkyl ether carboxylic acid, coconut oil alkanolamine, coconut fatty alcohol polyglycol ether, β-naphtholethoxylate, and block propylene oxide-ethylene oxide are present in an amount of from about 0.1 to about 50 weight % solids, and
an alkyl naphthalene sulfonate is present in an amount of from about 15 to about 30 weight % solids.

7. The developer concentrate of claim 1 having a pH of from about 7 to about 13.

8. A developer solution provided by diluting the developer concentrate of claim 1 with at least 2 parts water to 1 part developer concentrate.

9. A developer solution provided by diluting the developer concentrate of claim 1 with at least 5 parts water to 1 part developer concentrate.

10. The developer solution of claim 7 having a pH of from about 7 to about 12.

11. A developer solution provided by diluting the developer concentrate of claim 6 with at least 2 parts water to 1 part developer concentrate.

12. A method of providing a lithographic printing plate comprising:
A) imagewise exposing a lithographic printing plate precursor to provide both exposed and non-exposed regions, and
B) processing said imagewise exposed printing plate precursor with a developer solution provided by diluting the developer concentrate of claim 1 with at least 2 parts water to 1 part developer concentrate.

13. The method of claim 12 wherein said developer concentrate is diluted with water prior to processing step B.

14. The method of claim 12 wherein said developer concentrate is diluted with water as processing step B is carried out.

15. The method of claim 12 wherein said lithographic printing plate precursor is a negative-working thermal lithographic printing plate precursor that is sensitive to infrared radiation.

16. The method of claim 12 wherein said lithographic printing plate precursor is a positive-working thermal lithographic printing plate precursor that is sensitive to infrared radiation.

17. The method of claim 12 wherein aid lithographic printing plate precursor is a non-thermal photosensitive lithographic printing plate precursor that is sensitive to actinic radiation.

18. The method of claim 12 wherein said developer solution is provided by diluting the developer concentrate of claim 1 with up to 10 parts water to 1 part developer concentrate.

19. The method of claim 12 wherein said developer solution comprises:
one or more alkyl ether carboxylic acid, coconut oil alkanolamine, coconut fatty alcohol polyglycol ether, 0-naphtholethoxylate, and block propylene oxide-ethylene oxide are present in an amount of from about 0. 1 to about 50 weight % solids, and
an alkyl naphthalene sulfonate is present in an amount of from about 15 to about 30 weight % solids.
